(19) United States
(12) Patent Application Publication
(10) Pub. No.: US 2015/0263110 A1
(43) Pub. Date: Sep. 17, 2015

(54) SEMICONDUCTOR DEVICE

(71) Applicant: Kabushiki Kaisha Toshiba, Tokyo (JP)

(72) Inventors: Yusuke Kawaguchi, Miura (JP); Tetsuro Nozu, Tokyo (JP); Shunsuke Katoh, Komatsu (JP)

(21) Appl. No.: 14/482,218

(22) Filed: Sep. 10, 2014

(30) Foreign Application Priority Data
Mar. 13, 2014 (JP) 2014-050258

(51) Int. Cl. H01L 29/417; H01L 29/78

(52) U.S. Cl. CPC H01L 29/41741; H01L 29/7813

(57) ABSTRACT

According to an embodiment, a semiconductor device includes a first region, a second region, a first electrode, a first semiconductor layer provided on the first electrode, a second semiconductor layer provided on the first semiconductor layer, a third semiconductor layer provided on the second semiconductor layer in the second region, second electrodes, third electrodes, a third insulator film, a fourth electrode, a fourth insulator film, and a fifth electrode. The third electrodes face the second semiconductor layer and the first semiconductor layer in the first region through a second insulator film. The third electrodes face the third semiconductor layer, the second semiconductor layer and the first semiconductor layer in the second region through the second insulator film. Some of the third electrodes extend from the first region to the second region, and the others of the third electrodes are provided separately from each other in the second region.

### CROSS REFERENCE TO RELATED APPLICATION

This application is based upon and claims the benefit of priority from the prior Japanese Patent Application No. 2014-050258 filed on Mar. 13, 2014 in Japan, the entire contents of which are incorporated herein by reference.

### FIELD

Embodiments described herein relate generally to a semiconductor device.

### BACKGROUND

A semiconductor device such as a power Metal Oxide Silicon Filed Effect Transistor (MOSFET) used, for example, for a switched-mode power supply preferably has a high withstand voltage.

### BRIEF DESCRIPTION OF THE DRAWINGS

FIG. 1 is a cross-sectional view of a semiconductor device 100 according to a first embodiment.

FIG. 2 is a cross-sectional view of the semiconductor device 100 according to the first embodiment.

FIG. 3 is a plan view viewing downward from C-C′ surfaces in FIGS. 1 and 2.

FIG. 4 is a plan view of a semiconductor device 101 according to a second embodiment.

FIG. 5 is a plan view of a semiconductor device 102 according to a third embodiment.

### DETAILED DESCRIPTION

According to an embodiment, a semiconductor device includes a first region, a second region, a first electrode, a first semiconductor layer, a second semiconductor layer, a third semiconductor layer, a plurality of second electrodes, a plurality of third electrodes, a third insulator film, a fourth electrode, a fourth insulator film, and a fifth electrode. The first semiconductor layer is provided on the first electrode and has a first conductivity type. The second semiconductor layer is provided on the first semiconductor layer and has a second conductivity type. The third semiconductor layer is provided on the second semiconductor layer in the second region and has the first conductivity type. The second electrodes face the second semiconductor layer and the first semiconductor layer in the first region through a first insulator film. The second electrodes face the third semiconductor layer, the second semiconductor layer and the first semiconductor layer in the second region through the first insulator film. The second electrodes extend over the first region and the second region. The third electrodes face the second semiconductor layer and the first semiconductor layer in the first region through a second insulator film. The third electrodes face the third semiconductor layer, the second semiconductor layer and the first semiconductor layer in the second region through the second insulator film. Some of the third electrodes extend from the first region to the second region, and the others of the third electrodes are provided separately from each other in the second region. The third insulator film is provided on the second semiconductor layer and the third electrodes in the first region. The fourth electrode is provided on the third insulator film and the second electrodes in the first region. The fourth insulator film is provided on the second electrodes in the second region. The fifth electrode is provided on the third semiconductor layer, the fourth insulator film, and the third electrodes in the second region.

Embodiments will now be explained with reference to the accompanying drawings.

### First Embodiment

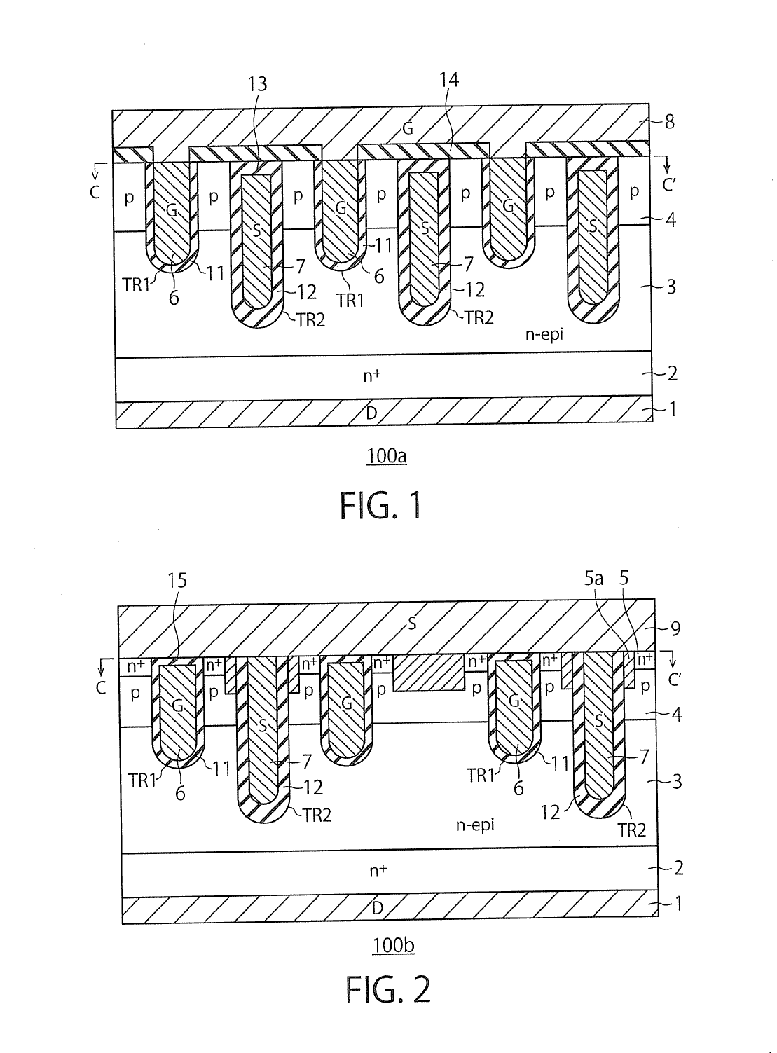

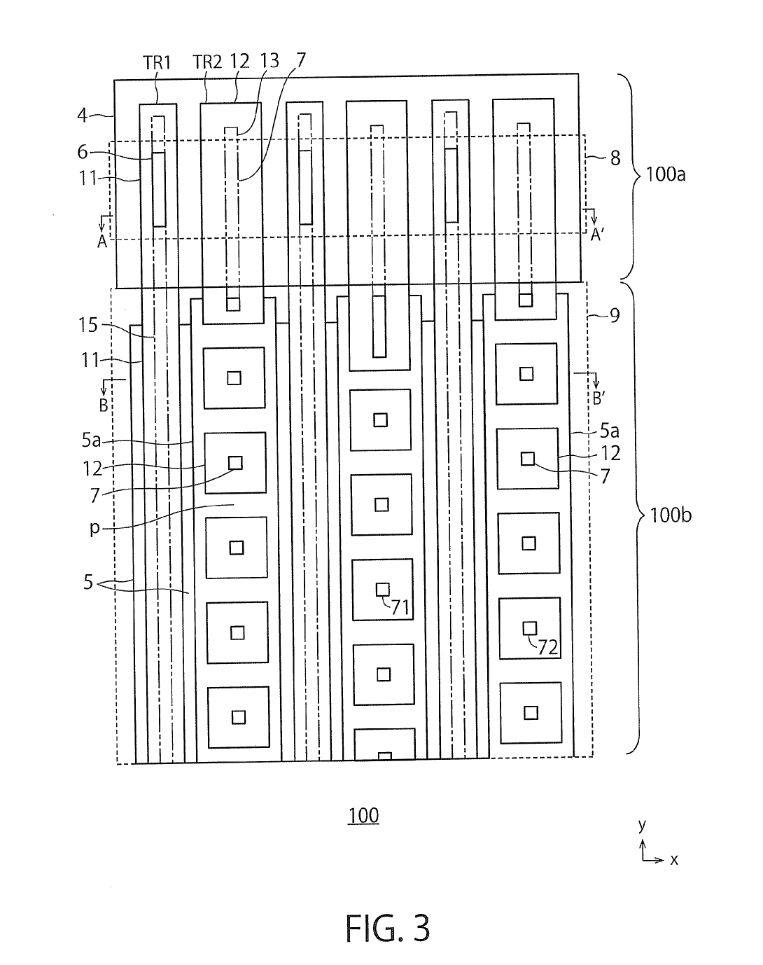

FIGS. 1 and 2 are cross-sectional views of a semiconductor device 100 according to a first embodiment. FIG. 3 is a plan view of the semiconductor device 100. FIG. 3 is a plan view viewing downward from C-C′ surfaces in FIGS. 1 and 2.

In FIG. 3, a terminal region (first region) 100a is a region in which current hardly flows. On the other hand, an active region (second region) 100b is a region in which current flows in the vertical direction of the drawing paper. The A-A′ cross-section in the terminal region 100a in FIG. 3 is illustrated in FIG. 1. The B-B′ cross-section in the active region 100b in FIG. 3 is illustrated in FIG. 2.

As illustrated in FIGS. 1 and 2, the semiconductor device 100 includes a drain electrode (first electrode) 1, an n⁺-type semiconductor substrate (semiconductor substrate) 2, an n-type epitaxial layer (first semiconductor layer) 3, a p-type semiconductor layer (second semiconductor layer) 4, an n⁺-type semiconductor layer (third semiconductor layer) 5, a plurality of gate electrodes (second electrodes) 6, a plurality of source electrodes (third electrodes) 7, a gate electrode (fourth electrode) 8, a source electrode (fifth electrode) 9, insulator films (first insulator films) 11, insulator films (second insulator films) 12, insulator films 13, and insulator films (third insulator films) 14.

First, the cross-section in the terminal region 100a illustrated in FIG. 1 will be described. The drain electrode 1, for example, made of aluminum is provided under the semiconductor substrate 2. On the other hand, the n-type epitaxial layer 3 is provided on the semiconductor substrate 2. To reduce the on-resistance of the semiconductor device 100, the n-type epitaxial layer 3 preferably has a high impurity concentration. The p-type semiconductor layer 4 is provided as a base layer on the n-type epitaxial layer 3. Note that the drain electrode 1, the semiconductor substrate 2, the n-type epitaxial layer 3, and the p-type semiconductor layer 4 are provided to the terminal region 100a in common with the active region 100b.

A plurality of trenches (first trenches) TR1 penetrating the p-type semiconductor layer 4 and reaching the n-type epitaxial layer 3 is formed at intervals. The insulator films 11 that are, for example, silicon oxide films are provided inside the trenches TR1. In other words, the insulator films 11 are provided on the n-type epitaxial layer 3 at intervals.

Furthermore, the gate electrodes 6, for example, made of polysilicon are embedded in the trenches TR1 through the insulator films 11. In other words, the side surfaces of the gate electrodes 6 face the p-type semiconductor layer 4 and the n-type epitaxial layer 3 through the insulator films 11. The bottoms of the gate electrodes 6 face the n-type epitaxial layer 3 through the insulator films 11.

Furthermore, a plurality of trenches (second trenches) TR2 penetrating the p-type semiconductor layer 4 and reaching the n-type epitaxial layer 3 is formed. The insulator films 12 that are, for example, silicon oxide films are provided inside the trenches TR2. The source electrodes 7, for example, made of tungsten are embedded in the trenches TR2 through the insulator films 12. In other words, the side surfaces of the source electrodes 7 face the p-type semiconductor layer 4 and the n-type epitaxial layer 3 through the insulator films 12. The bottoms of the source electrodes 7 face the n-type epitaxial layer 3 through the insulator films 12.

Note that the insulator films 13 are provided on the source electrodes 7. On the other hand, insulator films are not provided on the gate electrodes 6.

The gate electrodes 6 and the source electrodes 7 are alternately provided through the insulator films 11 and 12 while placing the n-type epitaxial layer 3 and the p-type semiconductor layer 4 therebetween. In other words, the n-type epitaxial layer 3 and the p-type semiconductor layer 4 are provided at each space between the insulator film 11 and the insulator film 12.

The interlayer insulator films 14 that are, for example, silicon oxide films or silicon nitride films are provided on the p-type semiconductor layer 4, the insulator films 11, and the insulator films 13. The gate electrode 8, for example, made of aluminum is provided on the interlayer insulator films 14 and the gate electrodes 6. In other words, the gate electrode 8 is provided on the insulator films 14 while some parts of the gate electrode 8 extend downward. The parts face the p-type semiconductor layer 4 and the n-type epitaxial layer 3 through the insulator films 11.

On the cross-section of the terminal region 100a illustrated in FIG. 1, the insulator films 14 are placed between the drain electrode 1 and the gate electrode 8, and the insulator films 11 are placed between the drain electrode 1 and the source electrodes 7. Thus, current does not flow among the electrodes in the terminal region 100a.

Next, the cross-section of the active region 100b illustrated in FIG. 2 will be described while the differences from FIG. 1 will mainly be described. The n⁺-type semiconductor layer 5 is provided on the p-type semiconductor layer 4. P⁺-type regions (fourth semiconductor regions) 5a are provided at some parts of the n⁺-type semiconductor layer 5. The p⁺-type regions 5a reach the p-type semiconductor layer 4.

The trenches TR2 penetrating the n⁺-type semiconductor layer 5 and the p-type semiconductor layer 4 and reaching the n-type epitaxial layer 3 are formed at intervals. The insulator films 12 are provided inside the trenches TR2. In other words, the insulator films 12 are provided on the n-type epitaxial layer 3 at intervals.

The source electrodes 7 are embedded in the trenches TR2 through the insulator films 12. In other words, the side surfaces of the source electrodes 7 face the n⁺-type semiconductor layer 5, the p-type semiconductor layer 4 and the n-type epitaxial layer 3 through the insulator films 12. The bottoms of the source electrodes 7 face the n-type epitaxial layer 3 through the insulator films 12. The p⁺-type regions 5a contact the insulator films 12.

Furthermore, the trenches TR1 penetrating the n⁺-type semiconductor layer 5 and the p-type semiconductor layer 4 and reaching the n-type epitaxial layer 3 are formed. The insulator films 11 are provided inside the trenches TR1. The gate electrodes 6 are embedded in the trenches TR1 through the insulator films 11.

The insulator films 11 are provided on the gate electrodes 6. In other words, the side surfaces of the gate electrodes 6 face the n⁺-type semiconductor layer 5, the p-type semiconductor layer 4 and the n-type epitaxial layer 3 through the insulator films 11. The bottoms of the gate electrodes 6 face the n-type epitaxial layer 3 through the insulator films 11.

Note that the insulator films 15 are provided on the gate electrodes 6. On the other hand, insulator films are not provided on the source electrodes 7.

The gate electrodes 6 and the source electrodes 7 are alternately provided through the insulator films 11 and 12 while placing the p-type semiconductor layer 4 and the n⁺-type semiconductor layer 5 therebetween. In other words, the n-type epitaxial layer 3, the p-type semiconductor layer 4, and the n⁺-type semiconductor layer 5 are provided at each space between the insulator film 11 and the insulator film 12.

The source electrode 9, for example, made of aluminum is provided on the n⁺-type semiconductor layer 5, the insulator films 11, the insulator films 15, and the source electrodes 7. In other words, the source electrode 9 is provided on the n⁺-type semiconductor layer 5, the insulator films 11, and the insulator films 15 while some parts of the source electrode 9 extend downward. The parts face the n⁺-type semiconductor layer 5, the p-type semiconductor layer 4, and the n-type epitaxial layer 3 through the insulator films 12. The source electrode 9 contacts the p-type semiconductor layer 4 through the p⁺-type regions 5a.

Note that, when the gate electrode 8 in FIG. 1 and the source electrode 9 in FIG. 2 are formed in the same process, both of the electrodes are made of the same material.

As illustrated in the drawings, the trenches TR2 are formed with a depth deeper than that of the trenches TR1. The source electrodes 7 are formed with a depth deeper than the gate electrodes 6. The insulator films 12 for the source electrodes 7 are thicker than the insulator films 11 for the gate electrodes 6 because the withstand voltage required among the gate electrodes 6 and the drain electrode 1 differs from the withstand voltage among the source electrodes 7 and the drain electrode 1. Generally, the latter needs a higher withstand voltage. Thus, the insulator films 12 for the source electrodes 7 are preferably thicker.

On the cross-section illustrated in FIG. 2, the n⁺-type semiconductor substrate 2 and the n-type epitaxial layer 3 are included in a drain region. The n⁺-type semiconductor layer 5 is a source region. The p-type semiconductor layer 4 is a drift layer. As described below, current flows from the drain electrode 1 toward the source electrode 9.

Next, the plane of the semiconductor device 100 illustrated in FIG. 3 will be described. FIG. 3 is a plan view of the semiconductor device 100 viewed from the gate electrode 8 and source electrode 9 side. For convenience of description, an x-axis and a y-axis that are perpendicular to each other are specified as illustrated in the drawing. First, a terminal region 100a will be described.

The gate electrodes 6 that extend in the y-axis direction (in a certain direction) and have a nearly rectangular cross-section are provided in a striped pattern. The gate electrodes 6 extend to the active region 100b. Each of the insulator films 11 is provided so as to surround each of the gate electrodes 6. The p-type semiconductor layer 4 is placed among the insulator films 11 and the insulator films 12.

Furthermore, the gate electrode 8 (denoted with a dashed line in FIG. 3) across whole the semiconductor device 100 in the x-axis direction is provided. Thus, the gate electrodes 6 in the trenches TR1 are connected to each other through the gate electrode 8 (see FIG. 1). As a result, all of the gate electrodes 6 have the same potential.

Note that at least a part of each of the gate electrodes 6 (denoted with a solid line in FIG. 3) can be connected to the gate electrode 8. The other parts of each of the gate electrodes 6 (denoted with an alternate long and two short dashes line in FIG. 3) are insulated from the gate electrode 8 because the interlayer insulator films 14 are provided thereon.

The source electrodes 7 (denoted with an alternate long and two short dashes line in FIG. 3) that extend in the y-axis direction and have a nearly rectangular cross-section are provided in a striped pattern. The source electrodes 7 extend to the active region 100b. Each of the insulator films 12 is provided so as to surround each of the source electrodes 7. The source electrodes 7 in the trenches TR2 are not connected to the gate electrode 8 because the insulator films 13 are provided on the source electrodes 7 (see FIG. 1).

Next, the active region 100b will be described.

The gate electrodes 6 in a striped pattern (denoted with the alternate long and two short dashes line in FIG. 3) extend from the terminal region 100a to the active region 100b. In other words, the gate electrodes 6 extend over the terminal region 100a and the active region 100b. Each of the insulator films 11 is provided so as to surround each of the gate electrodes 6. Note that the insulator films 15 are provided on the gate electrodes 6.

The source electrodes 7 are provided in a dot pattern. More specifically, the source electrodes 7 are provided as an extension of one of the source electrodes 7 on the terminal region 100a in the y-axis direction while separating from each other. Then, each of the insulator films 12 is provided so as to surround each of the source electrodes 7. The insulator film 12 surrounding one of the source electrodes 7 is provided separately from an insulator film 12 surrounding another source electrode 7. Each of the p⁺-type regions 5a is placed around each of the insulator films 12. The n⁺-type semiconductor layer 5 is placed outside the p⁺-type regions 5a. Current can flow in the vertical direction of the drawing paper of FIG. 3 in the n⁺-type semiconductor layer 5 in which the insulator films 12 are not provided.

As described above, the source electrodes 7 are provided not in a striped pattern but in a dot pattern in the semiconductor device 100 according to the present embodiment. This can increase the rate of the effective region in the active region 100b, namely, the region in which the insulator films 12 are not provided (the region denoted with a reference sign p in FIG. 3). As a result, this can increase the flowing current. In other words, this can reduce the on-resistance.

Furthermore, the source electrodes 7 extending from the terminal region 100a are also included in the active region 100b. The source electrodes 7 are in a striped pattern and shorter than the gate electrodes 6. The source electrode 9 (denoted with a dashed line in FIG. 3) across whole of the semiconductor device 100 in the x-axis direction is provided. Thus, the source electrodes 7 in the trenches TR2 are connected to each other through the source electrode 9 (see FIG. 2).

The source electrode 9 is provided also on the source electrodes 7 extending from the terminal region 100a. The source electrodes 7 are connected to the source electrode 9. Thus, not only the source electrodes 7 in the trenches TR2 in the active region 100b but also the source electrodes 7 in the trenches TR2 in the terminal region 100a have the same potential as the source electrode 9. As described above, in the semiconductor device 100 according to the present embodiment, the source electrodes 7 do not get into a floating state in the terminal region 100a. Thus, the withstand voltage among the source electrodes 7 and the drain electrode 1 is maintained also in the terminal region 100a.

Note that at least a part of each of the source electrodes 7 extending from the terminal region 100a (a part denoted with a solid line in FIG. 3) can be connected to the source electrode 9. The other part of each of the source electrodes 7 (denoted with the alternate long and two short dashes line in FIG. 3) is insulated from the source electrode 9 because the insulator films 13 are provided thereon.

The placement of the dot pattern of the source electrodes 7 is not especially limited. For example, the source electrodes 7 may be placed in a matrix pattern. However, the source electrodes 7 are preferably placed alternately (in a staggered pattern) as illustrated in FIG. 3. For example, a source electrode 71 in a line is preferably placed out of alignment without being immediate lateral to a source electrode 72 in the next line. In other words, in the active region 100b, a source electrode 7 in a line along the y-axis direction is offset relative to a source electrode 7 in the next line in the y-axis direction. The source electrodes 7 are provided at predetermined pitches in the y-axis direction in the active region 100b. The offset amount (distance) of the source electrodes 7 in the y-axis direction is about half of the pitch.

Current flows especially at the regions near the source electrodes 7 in the part in which the insulator films 12 are not provided in the active region 100b in FIG. 3. As illustrated in FIG. 3, placing the source electrodes 7 not in a matrix pattern but in an alternate pattern can reduce the regions far from the source electrodes 7. As a result, this allows a larger current to flow.

Next, the operation of the semiconductor device 100 will be described. When the semiconductor device 100 is used, a load is connected between the drain electrode 1 in the semiconductor device 100 and a power source terminal (not illustrated in the drawings). The power source terminal is supplied, for example, with a direct voltage of 100 V. The source electrodes 7 and 9 are grounded. The gate electrodes 6 and 8 are supplied with the control voltage. The control signal is set at a high voltage (for example, 10 V) or a low voltage (for example, 0 V).

When the control voltage is set at a low voltage, a channel is not formed on the p-type semiconductor layer 4 illustrated in FIG. 2. This turns off the semiconductor device 100. As a result, current does not flow in the semiconductor device 100 and the load.

When the control voltage is set at a high voltage, n-type channels are formed at the regions near the gate electrodes 6 in the p-type semiconductor layer 4 illustrated in FIG. 2 (the interfaces with the insulator films 11). This causes electrons to move from the source electrode 9 to the drain electrode 1 in the active region 100b through the n⁺-type semiconductor layer 5, the n channels formed on the p-type semiconductor layer 4, the n-type epitaxial layer 3, and the n⁺-type semiconductor substrate 2. As described above, when the control voltage is set at a high voltage, the semiconductor device 100 is turned on to allow current to flow in the semiconductor device 100 and the load.

In that case, the current flows the parts in which the insulator films 12 are not provided in the active region 100b illustrated in FIG. 3 in the semiconductor device 100. As described before, providing the source electrodes 7 in a dot pattern can reduce the regions in which the insulator films 12 are provided and can allow a large current to flow in the load. All of the source electrodes 7 in the trenches TR2 in the terminal region 100a and the active region 100b have ground potential. In other words, neither the source electrodes 7 in the terminal region 100a nor the source electrodes 7 in the active region 100b get into a floating state. This can maintain the withstand voltage among the source electrodes 7 and the drain electrode 1 high.

Next, an exemplary method for producing the semiconductor device 100 will briefly be described. First, an n-type epitaxial layer that is to work as the n-type epitaxial layer 3 and a p-type semiconductor layer that is to work as the p-type semiconductor layer 4 are sequentially deposited on the n⁺-type semiconductor substrate 2. The n⁺-type semiconductor layer 5 is deposited on the p-type semiconductor layer deposited on the active region 100b.

Then, the trenches TR2 penetrating the deposited p-type semiconductor layer and n-type epitaxial layer (and the n⁺-type semiconductor layer in the active region 100b) are formed. Next, the internal surfaces of the trenches TR2 are oxidized. This forms the insulator films 12. Furthermore, the source electrodes 7 are embedded in the insulator films 12.

The trenches TR1 penetrating the deposited p-type semiconductor layer and n-type epitaxial layer (and the n⁺-type semiconductor layer in the active region 100b) are formed. Next, the internal surfaces of the trenches TR1 are oxidized. This forms the insulator films 11. Furthermore, the gate electrodes 6 are embedded in the insulator films 11.

After that, an insulator film that is to work as the insulator films 13 and 15 is deposited on the whole surface. Then, the insulator film deposited on the gate electrodes 6 in the terminal region 100a and the insulator film deposited on the source electrodes 7 in the active region 100b are selectively removed. This forms contact holes for connecting the gate electrodes 6 to the gate electrode 8 and contact holes for connecting the source electrodes 7 to the source electrode 9.

Next, an insulator film that is to work as the interlayer insulator films 14 is deposited on the whole surface of the terminal region 100a. The insulator films on the gate electrodes 6 are selectively removed. The above form the n-type epitaxial layer 3, the p-type semiconductor layer 4, the n⁺-type semiconductor layer 5, the gate electrodes 6, the source electrodes 7, and the insulator films 11 to 15.

After that, the metal materials of the gate electrode 8 and the source electrode 9 are deposited on the whole surface. Then, the metal materials deposited between the terminal region 100a and the active region 100b are removed. This forms the gate electrode 8 connected to the gate electrodes 6 in the trenches TR1 in the terminal region 100a while forming the source electrode 9 connected to the source electrodes 7 in the trenches TR2 in the active region 100b.

The semiconductor device 100 is produced as described above. Note that each process can be performed with a well-known technique. For example, a thermal oxidation method can be used for forming insulator films in the trenches TR1 and TR2. To form the trenches TR1 and TR2 at specified positions or to selectively remove the films, a lithography technique or an etching technique can be used. Furthermore, a Chemical Vapor Deposition (CVD) method can be used for the deposition of the semiconductor layers.

As described above, in the first embodiment, the source electrodes 7 are provided in a dot pattern in the active region 100b. This can increase the current to flow and reduce the on-resistance. Furthermore, providing the source electrode 9 at the upper portion of the active region 100b causes all the source electrodes 7 in the trenches TR2 in the terminal region 100a and the active region 100b to have the same potential as the source electrode 9. This can maintain the withstand voltage among the source electrodes 7 and the drain electrode 1 in the semiconductor device 10 high.

### Second Embodiment

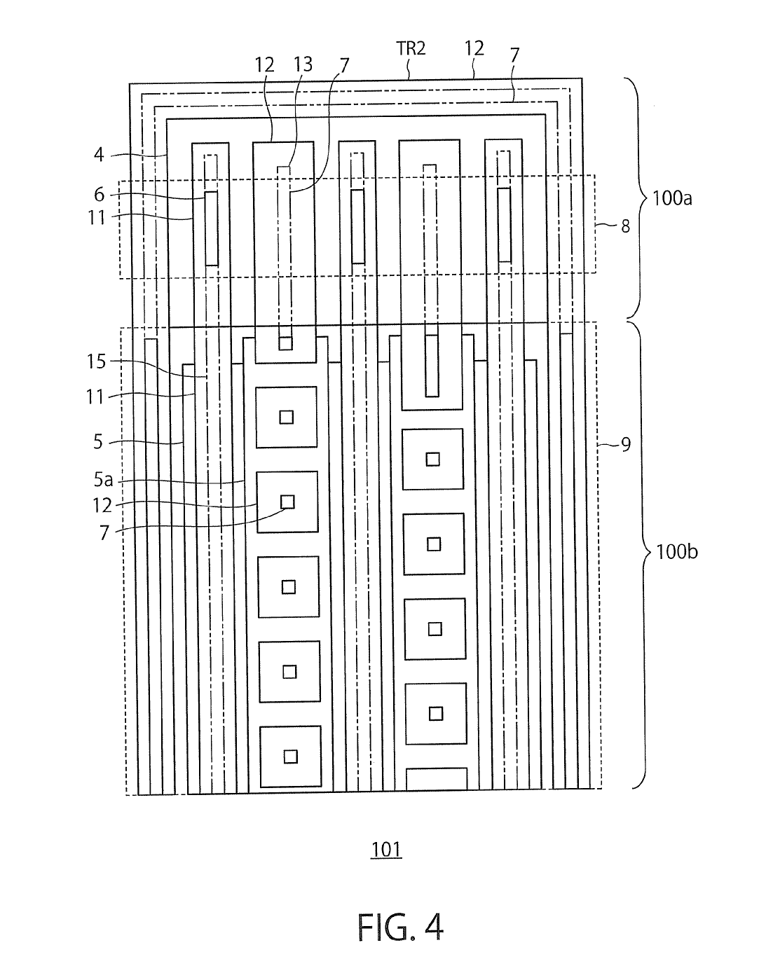

FIG. 4 is a plan view of a semiconductor device 101 according to a second embodiment. Hereinafter, the different points from FIG. 3 will mainly be described. In the semiconductor device 101, a trench TR2 is formed also at the outer periphery. An insulator film 12 is provided inside the trench TR2. Then, a source electrode 7 is embedded in the insulator film 12. In other words, the source electrode 7 is provided at the outer periphery of the semiconductor device 101.

The configuration described above completely separates the active region 100b using the trench TR2. This simplifies the withstand voltage design.

### Third Embodiment

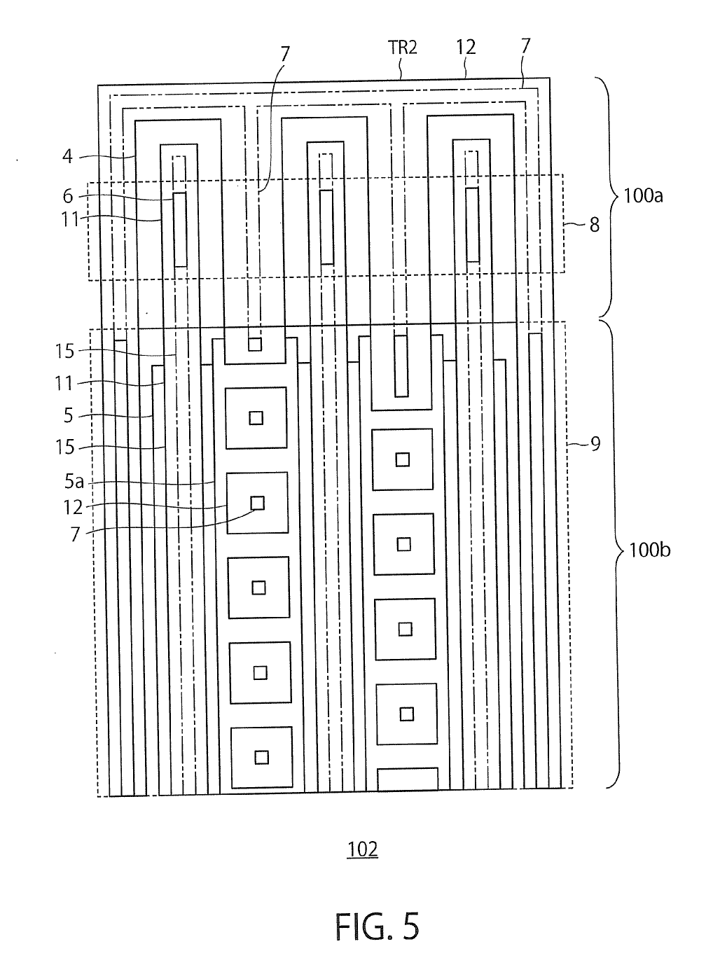

FIG. 5 is a plan view of a semiconductor device 102 according to a third embodiment. Hereinafter, the different points from FIG. 4 will mainly be described. In the semiconductor device 102, source electrodes 7 in a striped pattern in the terminal region 100a are connected to a source electrode 7 on the outer periphery.

The configuration described above simplifies the withstand voltage design, similarly to the second embodiment. Furthermore, it is not necessary to directly connect the source electrode 7 on the outer periphery to a source electrode 9 at the upper portion because the source electrodes 7 in a striped pattern are connected to the source electrode 7 on the outer periphery. This increases the flexibility of the layout of the source electrode 9.

Note that an example in which a first conductivity type is the n-type and a second conductivity type is the p-type has been described in each of the embodiments. However, the first conductivity type may be the p-type and the second conductivity type may be the n-type. Furthermore, each of the semiconductor layers may be formed with ion implantation in the semiconductor substrate, or may be formed by the deposition of a semiconductor film.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a first region;
a second region;
a first electrode;
a first semiconductor layer provided on the first electrode and having a first conductivity type;
a second semiconductor layer provided on the first semiconductor layer and having a second conductivity type;
a third semiconductor layer provided on the second semiconductor layer in the second region and having the first conductivity type;
a plurality of second electrodes that face the second semiconductor layer and the first semiconductor layer in the first region through a first insulator film, the second electrodes facing the third semiconductor layer, the second semiconductor layer and the first semiconductor layer in the second region through the first insulator film, the second electrodes extending over the first region and the second region;
a plurality of third electrodes that face the second semiconductor layer and the first semiconductor layer in the first region through a second insulator film, the third electrodes facing the third semiconductor layer, the second semiconductor layer and the first semiconductor layer in the second region through the second insulator film, some of the third electrodes extending from the first region to the second region, and the others of the third electrodes being provided separately from each other in the second region;
a third insulator film provided on the second semiconductor layer and the third electrodes in the first region;
a fourth electrode provided on the third insulator film and the second electrodes in the first region;
a fourth insulator film provided on the second electrodes in the second region; and
a fifth electrode provided on the third semiconductor layer, the fourth insulator film, and the third electrodes in the second region.

2. The semiconductor device according to claim 1, wherein the second electrodes are provided in a striped pattern while extending over the first region and the second region.

3. The semiconductor device according to claim 1, wherein the third electrodes are provided in a striped pattern in the first region.

4. The semiconductor device according to claim 1,
wherein the third electrodes are provided in a dot pattern in the second region.

5. The semiconductor device according to claim 4,
wherein the third electrodes extend in a certain direction and are provided in a striped pattern in the first region, and
the third electrodes are provided in the certain direction while separating from each other as an extension of each of the third electrodes in the first region.

6. The semiconductor device according to claim 5,
wherein one of the third electrodes in a line along the certain direction is offset relative to one of the third electrodes in an adjacent line in the certain direction, in the second region.

7. The semiconductor device according to claim 6,
wherein the third electrodes are provided at predetermined pitches in the certain direction in the second region, and
an offset amount of the third electrodes in the certain direction is ½ of the pitch.

8. The semiconductor device according to claim 4,
wherein, when being viewed from the fifth electrode side, the second insulator film surrounds each of the third electrodes provided in the dot pattern, and
the second insulator film surrounding one of the third electrodes is provided separately from the second insulator film surrounding another third electrode in the second region.

9. The semiconductor device according to claim 1,
wherein potential of the third electrodes in the first region is equal to potential of the third electrodes in the second region.

10. The semiconductor device according to claim 1,
wherein one of the third electrodes is provided on an outer periphery of the semiconductor device.

11. The semiconductor device according to claim 10,
wherein the third electrodes extending from the first region to the second region are connected to the third electrode provided on the outer periphery of the semiconductor device.

12. The semiconductor device according to claim 1,
wherein the second insulator film is thicker than the first insulator film.

13. The semiconductor device according to claim 1,
wherein the second electrodes and the third electrodes are alternately provided in the first region.

14. The semiconductor device according to claim 1,
wherein the first insulator film is provided inside a plurality of first trenches penetrating the second semiconductor layer and reaching the first semiconductor layer,
the second electrodes are embedded in the first trenches through the first insulator film,
the second insulator film is provided inside a plurality of second trenches penetrating the second semiconductor layer and reaching the first semiconductor layer, and
the third electrodes are embedded in the second trenches through the second insulator film.

15. The semiconductor device according to claim 1,
wherein the third electrodes are formed with a depth deeper than the second electrodes.

16. The semiconductor device according to claim 1, further comprising:
a semiconductor substrate provided on the first electrode and having the first conductivity type,
wherein the first semiconductor layer is provided on the semiconductor substrate.

17. The semiconductor device according to claim 1,
wherein the second electrodes are connected to each other through the fourth electrode.

18. The semiconductor device according to claim 1,
wherein the third electrodes are connected to each other through the fifth electrode.

19. The semiconductor device according to claim 1, further comprising:
a fourth semiconductor region provided at a part of the third semiconductor layer, reaching the second semiconductor layer and having the second conductivity type,
wherein the fifth electrode contacts the second semiconductor layer through the fourth semiconductor region.

20. The semiconductor device according to claim 19,
wherein the fourth semiconductor region contacts the second insulator film.
